(19) United States
(12) Patent Application Publication
(10) Pub. No.: US 2019/0267236 A1
(43) Pub. Date: Aug. 29, 2019

(54) METHOD AND APPARATUS FOR FORMING SILICON FILM, GERMANIUM FILM, OR SILICON GERMANIUM FILM

(71) Applicant: TOKYO ELECTRON LIMITED, Tokyo (JP)

(72) Inventor: Satoshi TAKAGI, Nirasaki City (JP)

(21) Appl. No.: 16/283,138

(22) Filed: Feb. 22, 2019

(30) Foreign Application Priority Data
Feb. 23, 2018 (JP) 2018-030576

(51) Int. Cl. H01L 21/02; C23C 16/24; C23C 16/28; C23C 16/30; C23C 16/52; C23C 16/56; C30B 25/18; C30B 29/06; C30B 29/08; C30B 29/52; C30B 25/16

(52) U.S. Cl. CPC H01L 21/02532; C30B 25/16; H01L 21/02661; H01L 21/02592; H01L 21/0262; H01L 21/02667; H01L 21/02428; H01L 21/02634; C23C 16/24; C23C 16/28; C23C 16/30; C23C 16/52; C23C 16/56; C30B 25/18; C30B 29/06; C30B 29/08; C30B 29/52; H01L 21/02381

(57) ABSTRACT

There is provided a method of forming a silicon film, a germanium, or a silicon germanium film on a surface to be processed of a workpiece, which has single crystalline silicon, single crystalline germanium, or single crystalline silicon germanium as the surface to be processed, includes: a first process of preparing the workpiece; a second process of adsorbing a halogen element on the surface to be processed of the workpiece; and a third process of forming an amorphous silicon film, an amorphous germanium film, or an amorphous silicon germanium film on the surface to be processed of the workpiece by supplying a source gas for forming a silicon film, a germanium film, or a silicon germanium film to the workpiece.

### CROSS-REFERENCE TO RELATED APPLICATION

This application is based upon and claims the benefit of priority from Japanese Patent Application No. 2018-030576, filed on Feb. 23, 2018, in the Japan Patent Office, the entire contents of which are incorporated herein in by reference.

### TECHNICAL FIELD

The present disclosure relates to a method and an apparatus for forming a silicon film, a germanium film, or a silicon germanium film.

### BACKGROUND

In a semiconductor manufacturing process, epitaxial growth method is widely used as a method for forming, for example, a new semiconductor layer on a semiconductor substrate. A typical example is vapor-phase epitaxial growth of a new single crystalline layer of silicon (Si) on single crystalline silicon.

In addition to Si, silicon germanium (SiGe) or germanium (Ge) is attracting attention as a semiconductor material capable of realizing higher performance of a semiconductor integrated circuit device. Thus, vapor-phase epitaxial growth of SiGe or Ge on single crystalline Si, SiGe, or Ge is also being investigated.

However, the vapor-phase epitaxial growth of Si, SiGe, or Ge on a single crystal such as single crystalline Si has a problem in that, if residual oxygen exists, amorphous growth occurs in the portions where the residual oxygen exists, irrespective of homoepitaxial growth for epitaxially growing the same kind of material or heteroepitaxial growth for epitaxially growing different kinds of material (e.g., epitaxial growth of SiGe on a single crystalline Si). Thus, due to the coexistence of epitaxial growth and amorphous growth, the surface of a grown film becomes rough. In the case of heteroepitaxial growth, due to a misfit dislocation caused by difference in lattice constant, a cross hatch pattern, in which the epitaxial growth rate locally changes, occurs, which also roughens the surface of the grown film.

In order to prevent the surface from being roughened, it is considered effective to grow an amorphous film on the entire surface of a single crystal such as single crystalline Si. In addition, in some cases, for example, a case in which a metal source/drain is formed on single crystalline Si, it is necessary to form amorphous SiGe on single crystalline Si.

In the related art, there has been known a technique for uniformly forming amorphous silicon on a single crystalline Si substrate. In the technique, a thin first amorphous Si film is formed on a single crystalline Si substrate at a low temperature, at which poly-crystallization hardly occurs, using Si₂H₆ gas as a first gas, and then a thick second amorphous Si film is formed on the first amorphous Si film at a raised temperature using SiH₄ gas as a second gas.

However, when a Si film, a SiGe film, or a Ge film is formed on a single crystal such as single crystalline Si, a film deposited on the underlying single crystal drags the lattice constant of the underlying single crystal and is likely to epitaxially grow. Thus, it is difficult to form a perfect amorphous film even by the technique described above.

### SUMMARY

Some embodiments of the present disclosure provide a technique capable of forming a substantially complete amorphous silicon film, germanium film, or silicon germanium film on single crystalline silicon, single crystalline germanium, or single crystalline silicon germanium.

According to one embodiment of the present disclosure, there is provided a method of forming a silicon film, a germanium film, or a silicon germanium film on a surface to be processed of a workpiece having single crystalline silicon, single crystalline germanium, or single crystalline silicon germanium as the surface to be processed. The method includes: a first process of preparing the workpiece; a second process of adsorbing a halogen element on the surface to be processed of the workpiece; and a third process of forming an amorphous silicon film, an amorphous germanium film, or an amorphous silicon germanium film on the surface to be processed of the workpiece by supplying a source gas for forming a silicon film, a germanium film, or a silicon germanium film to the workpiece.

According to another embodiment of the present disclosure, there is provided an apparatus of forming a silicon film, a germanium film, or a silicon germanium film on a surface to be processed of a workpiece having single crystalline silicon, single crystalline germanium, or single crystalline silicon germanium as the surface to be processed. The apparatus includes: a processing container configured to accommodate the workpiece in the processing container; a gas supply mechanism configured to supply a source gas for forming the silicon film, the germanium film, or the silicon germanium film, a halogen element-containing gas, and an inert gas to the processing container; a heating device configured to heat the workpiece; an exhaust device configured to evacuate an interior of the processing container; and a controller configured to control the gas supply mechanism, the heating device, and the exhaust device. The controller performs control to: in a state in which the workpiece is disposed in the processing container, adsorb the halogen element-containing gas on the surface to be processed of the workpiece by supplying the halogen element-containing gas from the gas supply mechanism to the processing container while controlling a pressure and a temperature in the processing container by the exhaust device and the heating device; and then form an amorphous silicon film, an amorphous germanium film, or an amorphous silicon germanium film on the surface to be processed of the workpiece by supplying the source gas from the gas supply mechanism to the surface to be processed of the workpiece.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a flowchart illustrating an example of a film forming method according to a first embodiment of the present disclosure.

FIGS. 2A to 2D are process sectional views illustrating an example of the film forming method according to the first embodiment of the present disclosure.

FIGS. 3A and 3B are sectional views illustrating a state where a Si film is formed by directly supplying a Si source to single crystalline silicon.

FIGS. 4A and 4B are views for illustrating a film formation mechanism when a Si film is formed by directly supplying a Si source to single crystalline silicon.

FIGS. 5A and 5B are views for illustrating a film formation mechanism when a Si film is formed after a halogen element is adsorbed on single crystalline silicon.

FIG. 6 is a view illustrating a state where an a-Si film, which is formed by the film forming method according to the first embodiment of the present disclosure, is crystallized.

FIG. 7 is a view comparing a haze of a film surface and a film thickness in the cases where a Si film was directly formed on a surface to be processed in which single crystalline Si was exposed, and where a Si film was formed after a halogen element adsorption process using Cl₂ gas was performed.

FIG. 8 is a view showing measurement results of a refractive index and an extinction coefficient, which are crystal-amorphous indicators, in the cases where a Si film was directly formed on a surface to be processed in which single crystalline Si was exposed, and where a Si film was formed after a halogen element adsorption process using Cl₂ gas was performed on a surface to be processed in which single crystalline Si was exposed.

FIG. 9 is a view showing measurement results of a refractive index and an extinction coefficient, which are crystal-amorphous indicators, in the cases where a Si film was formed after a halogen element adsorption process using Cl₂ gas was performed on a surface to be processed in which single crystalline Si was exposed, and where vacuum evacuation was performed after the formation of the Si film.

FIG. 10 is a view showing measurement results of an oxygen (O) concentration and a Cl concentration in a thickness direction of a film using a secondary ion mass spectrometer (SIMS), in the cases where a Si film was directly formed on a surface to be processed in which single crystalline Si was exposed, and where a Si film was formed after a halogen element adsorption process using Cl₂ gas was performed on a surface to be processed in which single crystalline Si was exposed.

FIG. 11 is a flowchart illustrating an example of a film forming method according to a second embodiment of the present disclosure.

FIGS. 12A to 12D are process sectional views illustrating an example of the film forming method according to the second embodiment of the present disclosure.

FIGS. 13A and 13B are sectional views illustrating a state where a SiGe film is formed by directly supplying a Si source gas and a Ge source gas to single crystalline silicon.

FIG. 14 is a view illustrating a state where an a-SiGe film, which is formed by the film forming method according to the second embodiment of the present disclosure, is crystallized.

FIG. 15 is a vertical sectional view illustrating an example of a film forming apparatus capable of performing the film forming methods according to the first and second embodiments of the present disclosure.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, embodiments of the present disclosure will be described in detail with reference to the accompanying drawings.

### First Embodiment

First, a film forming method according to a first embodiment of the present disclosure will be described. In the present embodiment, a case where an amorphous film formed of the same material is formed on a single crystal will be described.

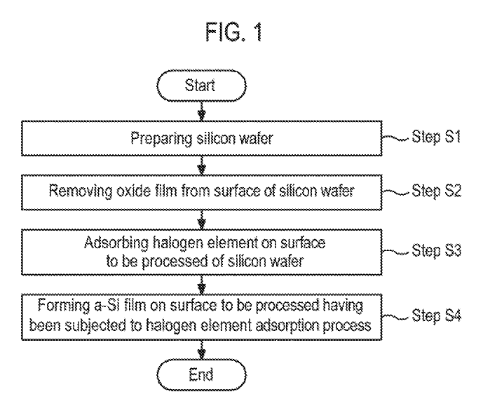

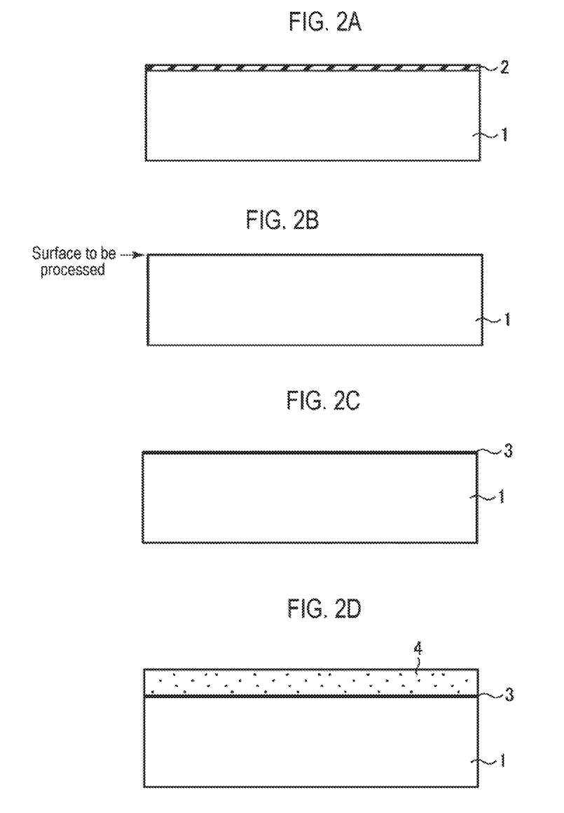

FIG. 1 is a flowchart illustrating an example of a film forming method according to the first embodiment of the present disclosure, and FIGS. 2A to 2D are process sectional views schematically illustrating states of a substrate to be processed during the film forming method of the first embodiment.

First, a silicon wafer 1, which is a single crystalline silicon substrate, is prepared as a workpiece having a surface to be processed of single crystalline Si (step S1, see FIG. 2A).

On surfaces including the surface to be processed of the silicon wafer 1, an oxide film 2, which is formed of a natural oxide film or a chemical oxide formed by a chemical reaction with a substance other than the atmospheric air, is formed.

Next, the oxide film 2 including the natural oxide film formed on the surface of the silicon wafer 1 is removed (step S2, see FIG. 2B).

A process for removing the oxide film 2 may be performed using a hydrogen-containing substance. An example is a chemical oxide removal (COR) process using ammonia (NH₃) gas and hydrogen fluoride (HF) gas as a hydrogen-containing gas. Alternatively, a high-temperature treatment using hydrogen or a hydrogen plasma treatment may be used. Alternatively, a wet treatment using a chemical liquid containing hydrogen such as dilute hydrofluoric acid (DHF) may be used. By removing the oxide film 2 using the above-described methods, the surface of the silicon wafer 1 becomes a hydrogen-terminated clean surface (including dangling bonds). Among the above-described methods, the COR process is advantageous in that the COR process is a dry process that allows a subsequent step to be performed in-situ.

Next, a halogen element 3 is adsorbed on the surface to be processed of the silicon wafer 1 (step S3, see FIG. 2C).

This process is performed by supplying a halogen element-containing gas to the silicon wafer 1. As the halogen element, for example, Cl, F, Br, and I may be used, and as the halogen element-containing gas, for example, Cl₂ gas, HCl gas, HBr gas, Br₂ gas, HI gas, I₂ gas, ClF₃ gas, and F₂ gas may be used. By supplying the halogen element-containing gas, the halogen element-containing gas is adsorbed on the surface to be processed, which results in adsorption of the halogen element 3.

A process condition varies according to the gas to be used. However, in some embodiments, a temperature may fall in the range of 50 to 400 degrees C. and a pressure may fall in the range of 1.33 to 666.6 Pa (0.01 to 5 Torr).

When the Cl₂ gas is used as the halogen element-containing gas, an example of the process condition in step S3 is as follows.

Cl₂ gas flow rate: 300 to 5,000 sccm

Processing time: 0.5 to 5 minutes

Processing temperature: 50 to 400 degrees C.

Processing pressure: 1.33 to 666.6 Pa (0.01 to 5 Torr)

Next, an amorphous Si (also referred to as a-Si) film 4 is formed by supplying a silicon source gas to the surface to be processed of the silicon wafer 1 on which the halogen element adsorption process is performed (step S4, see FIG. 2D).

When forming the a-Si film 4, as a silicon source gas, a gas containing hydrogen and silicon such as disilane (Si₂H₆) gas, monosilane (SiH₄) gas, trisilane (Si₃H₈) gas, or tetrasilane (Si₄H₁₀) may be used. Alternatively, hexachlorodisilane (Si₂Cl₆) gas, which is a chlorine-containing compound gas, may be used. Alternatively, a silane gas containing an amino group, for example, BTBAS, 3DMAS, or DIPAS, may be used. Further, a dopant may be doped at the time of forming the a-Si film 4. As a dopant gas, PH₃, P₂H₄, or PCl₃ for doping phosphorus (P), or B₂H₆ or BCl₃ for doping boron (B) may be used.

When the disilane (Si₂H₆) gas is used as the silicon source gas, an example of process condition in step S4 is as follows.

Si₂H₆ gas flow rate: 10 to 1,000 sccm

Processing time: 1 minute or more

Processing temperature: 350 to 450 degrees C.

Processing pressure: 13.3 to 1,333.3 Pa (0.1 to 10 Torr)

By performing steps S1 to S4 described above, it is possible to form a substantially complete amorphous (non-crystalline) Si film (a-Si film) 4 on the surface to be processed of the silicon wafer 1 formed of single crystalline Si.

Details will be described below.

When the silicon source gas is directly supplied to clean single crystalline silicon from which the oxide film on the surface has been removed, the lattice constant of the underlying single crystal is dragged and epitaxial growth easily occurs. Thus, in general, a substantially single crystalline Si film is formed.

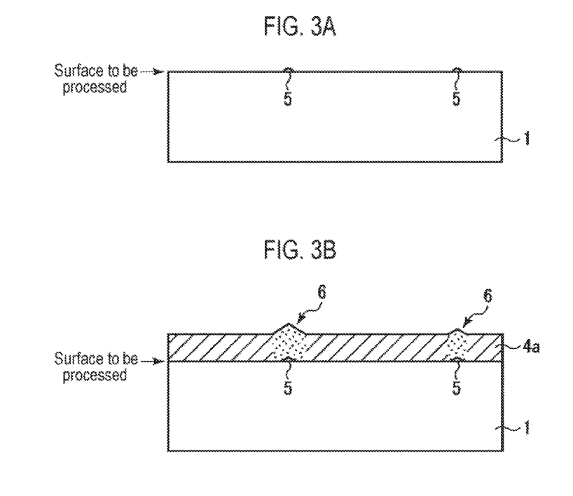

However, even after the oxide film removal process in step S2 is performed, when viewed microscopically, a small amount of residual oxygen 5 exists in many cases as shown in FIG. 3A. In this state, when a silicon source is supplied, epitaxial growth occurs in a portion where the residual oxygen 5 does not exist, whereas the epitaxial growth is hindered and amorphous growth occurs in a portion where the residual oxygen 5 exists. Thus, the epitaxial growth and the amorphous growth coexist in a finally obtained Si film 4a. Since a growth rate of amorphous Si is higher than a growth rate of crystalline Si, as shown in FIG. 3B, the portion where the residual oxygen 5 exists and the amorphous Si grows becomes a facet 6 of a pyramidal protrusion, which results in roughening the surface.

In order to prevent the surface from being roughened, it is effective to form an a-Si film on the entire surface of single crystalline Si. However, as described above, since single crystal is likely to be formed on the single crystalline Si, it is difficult to grow an amorphous film on the entire surface.

Therefore, in the present embodiment, the halogen element 3 is adsorbed on the surface of the single crystalline Si exposed on the surface to be processed of the silicon wafer 1, so that hydrogen-terminated portions and some dangling bonds of the single crystalline Si are terminated by the halogen element. For example, by using the Cl₂ gas as the halogen element-containing gas, Cl is adsorbed as the halogen element to form Cl-terminated portions. This makes it possible to grow a complete amorphous film on the single crystalline Si.

The mechanism will be described below.

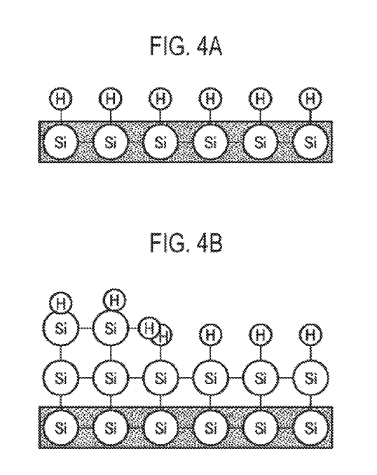

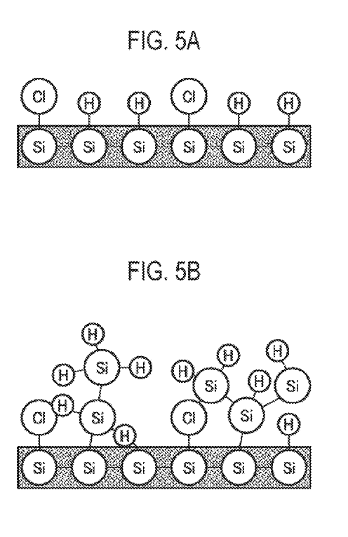

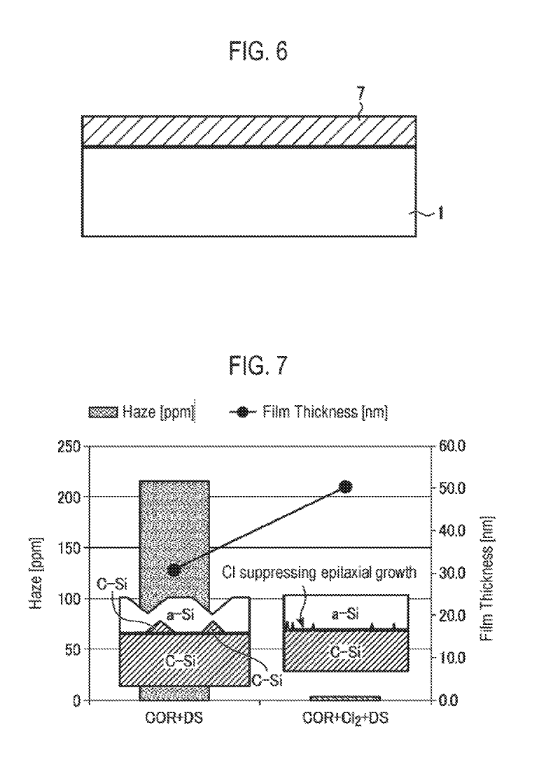

As shown in FIG. 4A, the surface of single crystalline Si after removing the oxide film is hydrogen-terminated (including dangling bonds). However, since hydrogen termination has a weak bond, when the silicon source gas is supplied to the surface, H is easily substituted by Si and Si is epitaxially grown, as shown in FIG. 4B. In contrast, when Cl as a halogen element is adsorbed on the surface of single crystalline silicon, some of the silicon-terminating hydrogen are substituted by Cl as a halogen element and Cl termination is formed, as shown in FIG. 5A. In this state, when the silicon source gas is supplied, since Cl as a halogen element has a stronger bond with underlying Si than H, silicon-terminating Cl is not substituted by Si. Thus, mismatch in lattice occurs and the epitaxial growth is hindered, as shown in FIG. 5B. Therefore, by adsorbing the halogen element on the surface of the single crystalline Si, it is possible to form a substantially complete amorphous Si film (a-Si film) 4 on the entire surface of the single crystalline Si.

By forming the substantially complete amorphous Si film 4 as described above, it is possible to suppress the surface from being roughened due to the occurrence of facets.

Further, although the halogen element such as Cl is adsorbed on the surface of the silicon wafer 1, the influence of the halogen element on electric characteristics of the semiconductor substrate is extremely small, which is also a great advantage.

In addition, by performing a crystallization process after the a-Si film 4 is formed as described above, it is possible to turn the a-Si film 4 into a single crystalline Si film 7 and to obtain a state in which the single crystalline Si film 7 as a homoepitaxial growth film is formed on the single crystalline Si film. After performing the crystallization process, the single crystalline Si film 7 is maintained in the state in which the surface is suppressed from being roughened, like the a-Si film 4.

The crystallization process may be carried out in-situ in a processing container of a film-forming apparatus in which the a-Si film 4 is formed. The a-Si film 4 is in an unstable state and is very easily crystallized. Thus, it is possible to easily crystallize the a-Si film 4 by performing vacuum evacuation or annealing as the crystallization process. Both of the vacuum evacuation and the annealing are processes for achieving crystallization by desorbing H or the like contained in the a-Si film 4. In the case of vacuum evacuation, it is only necessary to simply perform vacuum evacuation in an inert gas atmosphere or the like so as to desorb H or the like in the a-Si film 4, without raising a temperature. In the case of annealing, it is only necessary to raise a temperature in an inert gas atmosphere or the like so as to desorb H or the like by heat. The temperature in the annealing process may be set to be equal to or higher than a film formation temperature.

When another process enters before turning the a-Si film 4 into the single crystalline Si film 7 by the crystallization process, after the a-Si film 4 is formed, the silicon wafer 1 may be taken out of the processing container and the crystallization process may be performed ex-situ.

In addition, for example, after the a-Si film 4 is formed, a metal film may be formed on the a-Si film 4 and annealed to form metal silicide. If an amorphous film has been formed before the silicidation process, progress of the silicidation process is promoted.

In the above-described examples, the a-Si film is formed on single crystalline Si. However, in the present embodiment, the same procedure may be performed when forming an amorphous Ge (also referred to as “a-Ge”) film on single crystalline Ge or when forming an amorphous SiGe (also referred to as “a-SiGe”) film on single crystalline SiGe.

As a germanium source gas for forming the amorphous Ge film, a gas containing hydrogen and germanium, such as monogermane (GeH₄) gas, digermane (Ge₂H₆) gas, and trigermane (Ge₃H₈), may be used. Alternatively, a chlorine-containing compound gas, such as GeH₃Cl, GeH₂Cl₂, and a GeHCl₃, may be used. When forming the amorphous SiGe film, a silicon source gas such as monosilane (SiH₄) gas or disilane (Si₂H₆) gas and a germanium source gas such as monogermane (GeH₄) gas or digermane (Ge₂H₆) gas may be used. Further, a dopant may be doped during the film formation. As a dopant gas, PH₃, P₂H₄, or PCl₃ for doping phosphorus (P), or B₂H₆ or BCl₃ for doping boron (B) may be mentioned.

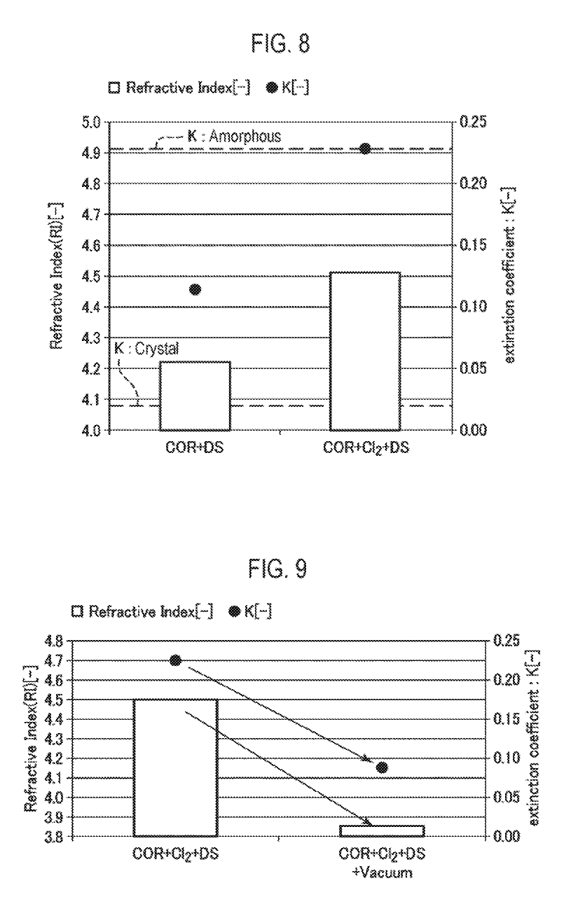

Actually, a haze of a film surface and a film thickness obtained in two cases were compared. In the one case (COR+DS), an oxide film on the surface of a silicon wafer was removed by performing a COR process and then a Si film was directly formed on a surface to be processed in which single crystalline Si was exposed using disilane (Si₂H₆). In another case (COR+Cl₂+DS), a halogen element adsorption process using Cl₂ gas was performed after the COR process, and then a Si film was formed using disilane (Si₂H₆). In addition, for the respective films, a refractive index (RI) and an extinction coefficient (K), which are crystal-amorphous (non-crystalline) indicators, were measured. The results are shown in FIGS. 7 and 8. As shown in FIGS. 7 and 8, in the case of COR+DS, since an amorphous state and a crystalline state coexisted, the haze value of the formed Si film was large, and the RI and K values of the formed. Si film indicated that the formed Si film was crystal. On the other hand, in the case of COR+Cl₂+DS, the haze value of the formed Si film was small, the RI and K values indicated that the formed Si film was amorphous (non-crystalline), and the film thickness was also larger than that in the case of COR+DS. FIG. 7 shows states of films in the cases of COR+DS and COR+Cl₂+DS, but the states of films schematically show epitaxial growth only and do not show actual amounts of the amorphous state and the crystalline state.

From the above, it has been confirmed that in the case of COR+DS, Si is epitaxially grown and also partially amorphous grown due to the residual oxygen so that roughening the surface occurs, whereas in the case of COR+Cl₂+DS, the Si film is substantially complete amorphous and the surface is not roughened.

Next, with respect to the Si film obtained by COR+Cl₂+DS and a Si film obtained by further performing vacuum evacuation after COR+Cl₂+DS (COR+Cl₂+DS+Vacuum), the RI and K values were measured. As a result, as shown in FIG. 9, it has been confirmed that by the vacuum evacuation, the RI and the K values are reduced and the Si films are crystallized. Even when the vacuum evacuation was performed, the surface roughness of the Si film was kept small.

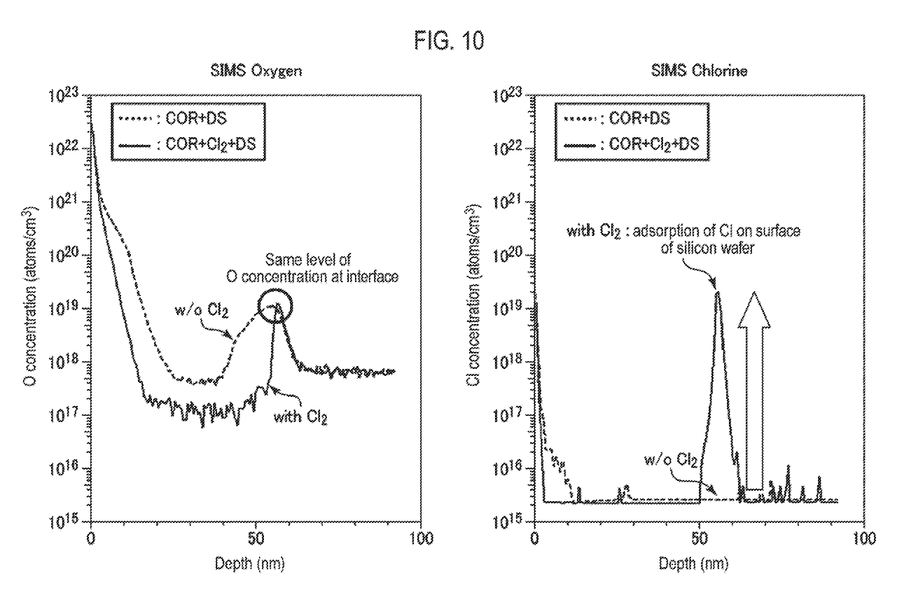

Next, with respect to the Si film formed by COR+DS and the Si film formed by COR+Cl₂+DS, oxygen (O) concentrations and Cl concentrations in a thickness direction of the film were measured using a secondary ion mass spectrometer (SIMS). The results are shown in FIG. 10. As shown in FIG. 10, even when the adsorption process using Cl₂ gas was performed, the O concentration in the vicinity of the surface of the silicon wafer was not reduced and only the Cl concentration increased. Thus, it has been confirmed that epitaxial growth was hindered by Cl.

### Second Embodiment

Next, a film forming method according to a second embodiment of the present disclosure will be described. In the present embodiment, a case where an amorphous film formed of a different material is formed on a single crystalline will be described.

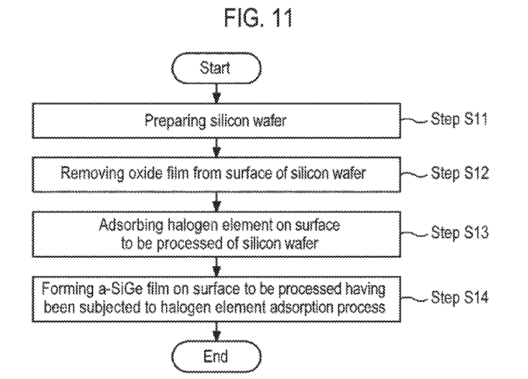

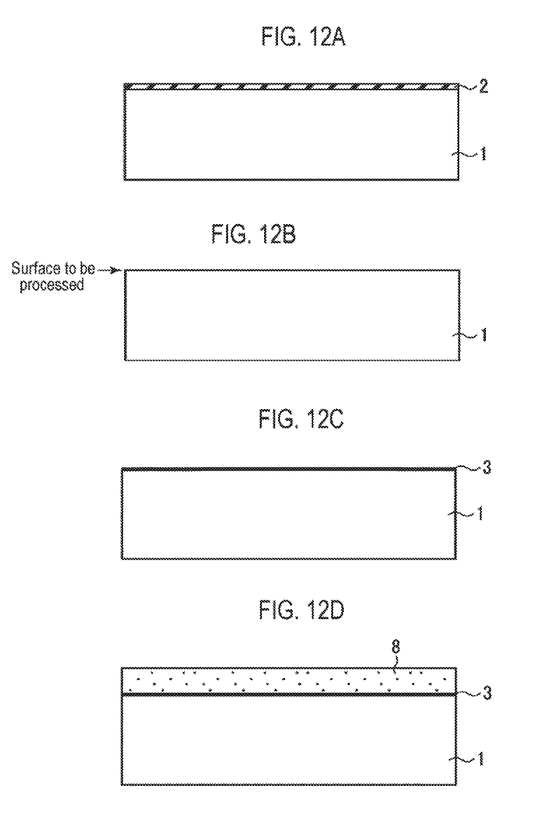

FIG. 11 is a flowchart illustrating an example of a film forming method according to the second embodiment of the present disclosure, and FIGS. 12A to 12D are process sectional views schematically illustrating states of a substrate to be processed.

First, a silicon wafer 1 is prepared as a workpiece having a surface to be processed as single crystalline Si (step S11, see FIG. 12A). Next, an oxide film 2 including a natural oxide film is removed from the surface of the silicon wafer 1 (step S12, see FIG. 12B). Next, a halogen element 3 is adsorbed on a surface of single crystalline Si exposed on the surface to be processed of the silicon wafer 1 (step S13, see FIG. 12C). Steps S11 to S13 described above are performed in the same manner as steps S1 to S3 of the first embodiment.

Next, an a-SiGe film 8 is formed by supplying a silicon source gas and a germanium source gas to the surface to be processed of the silicon wafer 1 on which the halogen element adsorption process has been carried out (step S14, see FIG. 12D).

When forming the a-SiGe film 8, as the silicon source gas, a gas containing hydrogen and silicon, such as monosilane (SiH₄) gas or disilane (Si₂H₆) gas, may be used. In addition, as the germanium source gas, a gas containing hydrogen and germanium, such as monogermane (GeH₄) gas or digermane (Ge₂H₆) gas, may be used.

When the monosilane (SiH₄) gas is used as the silicon gas and the monogermane (GeH₄) gas is used as the germanium gas, an example of process condition in step S14 is as follows.

SiH₄ gas flow rate: 0 to 5,000 sccm (greater than zero)

Ge₂H₄ gas flow rate: 0 to 5,000 sccm (greater than zero)

Processing time: 5 minutes or more

Processing temperature: 250 to 450 degrees C.

Processing pressure: 13.33 to 533.2 Pa (0.1 to 4 Torr)

By steps S11 to S14 described above, it is possible to form a substantially complete amorphous (non-crystalline) SiGe film (a-SiGe film) 8.

Details will be described below.

When the silicon source gas and the germanium source gas are directly supplied to clean single crystalline silicon from which the oxide film on the surface has been removed, the lattice constant of the underlying single crystal is dragged and epitaxial growth easily occurs. Thus, a substantially single crystalline SiGe film is formed.

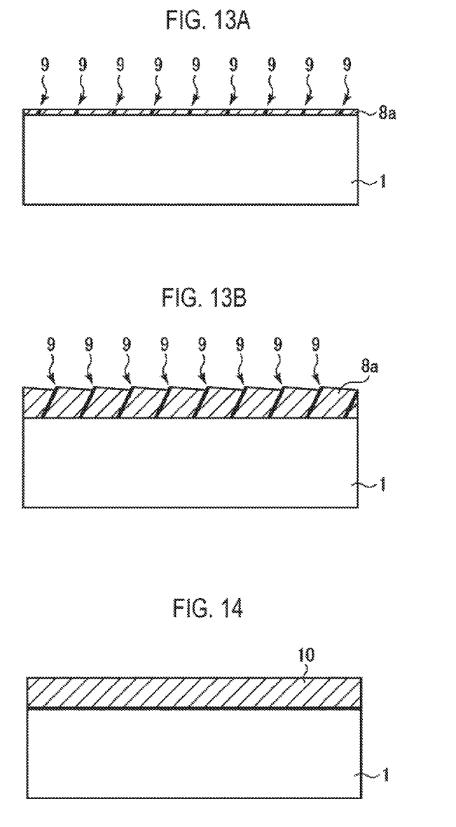

However, even after the oxide film removal process of step S12 is performed, as in the first embodiment, due to the existence of residual oxygen, epitaxial growth and amorphous growth coexist in an obtained SiGe film 8a. In addition, since the formation of the SiGe film 8a is heteroepitaxial growth, due to the difference in lattice constant between Si and SiGe, misfit transitions 9 caused by crystal mismatch occur in the SiGe film 8a, as shown in FIG. 13A. When crystals are grown in a state where the misfit transitions 9 has occurred, “steps along the misfit transitions 9” (cross hatch pattern) occur on the surface of the SiGe film 8a, as shown in FIG. 13B. Thus, the surface of the SiGe film 8a is roughened.

In order to prevent the surface from being roughened, it is effective to form an a-SiGe film on the entire surface of the single crystalline Si. However, as described above, it is difficult to form a complete amorphous SiGe film on the single crystalline Si.

Therefore, in the present embodiment, as in the first embodiment, a halogen element is adsorbed on the surface of the single crystalline Si exposed on the surface to be processed of the silicon wafer 1, so that the hydrogen-terminated portions and some dangling bonds of the single crystalline Si are terminated by the halogen element. For example, by using Cl₂ gas as the halogen element-containing gas, Cl is adsorbed as the halogen element to form Cl-terminated portions. This makes it possible to grow a complete amorphous film on the single crystalline Si.

By forming the a-SiGe film 8 as a substantially complete amorphous film as described above, it is possible to suppress the surface from being roughened due to the occurrence of facets and the cross hatch pattern.

Then, by performing the crystallization process after forming the a-SiGe film 8, as illustrated in FIG. 14, it is possible to turn the a-SiGe film 8 into a single crystalline SiGe film 10, and to obtain a state in which the single crystalline SiGe film 10 as a heteroepitaxial growth film is formed on the single crystalline Si film. After performing the crystallization process, the single crystalline SiGe film 10 is maintained in a state in which the surface is suppressed from being roughened, like the a-SiGe film 8.

The crystallization process may be carried out in-situ in a processing container of a film forming apparatus, as in the first embodiment. The a-SiGe film 8 is very easily crystallized. Thus, as in the first embodiment, it is possible to easily crystallize the a-SiGe film 8 by performing vacuum evacuation or annealing as the crystallization process. In the case of vacuum evacuation, it is only necessary to perform vacuum evacuation without raising a temperature. In the case of annealing, the temperature may be set to be equal to or higher than a film formation temperature.

When another process enters before the a-SiGe film 8 is turned into the single crystalline SiGe film 10 by the crystallization process, the silicon wafer 1 may be taken out of the processing container and the crystallization process may be performed ex-situ. For example, when a SiGe film is used for a source/drain, a silicon wafer in which the a-SiGe film 8 is formed on single crystalline silicon may be taken out from a film forming apparatus and an impurity implantation process may be performed on the a-SiGe film 8. Then, the crystallization process may be performed.

In addition, for example, after the a-SiGe film 8 is formed, a metal film may be formed on the a-Si film 4 and annealed to form metal silicide, as in the first embodiment. Even in this case, progress of the silicidation process is promoted.

In the above examples, the a-SiGe film is formed on single crystalline Si. However, in the present embodiment, the same procedure may be performed when forming an a-SiGe film or an a-Si film on single crystalline Ge or when forming an a-Si film or an a-Ge film on single crystalline SiGe.

In a practical example of forming the metal silicide, an a-SiGe film is formed on a silicon wafer as a single crystalline silicon substrate by the method of the second embodiment, and after an impurity implantation process, a source/drain formed of a single crystalline SiGe film is formed by performing a crystallization process. Then, any one of an a-Si film, an a-Ge film, and an a-SiGe film is formed on the single crystalline SiGe film according to corresponding one of the above embodiments, and a metal film such as a nickel film is formed. Then, metal silicide is formed by annealing. This allows the process of forming the source/drain necessitating a reduced electrical resistance to form an amorphous film on the substantially entire surface of a single crystal, to reduce the surface roughness, and to reduce the amount of oxygen in the interface of the amorphous film. Thus, the electrical resistance can be lowered. Further, by forming the silicide, it is possible to further reduce the resistance value of the entirety of the source/drain.

### <Processing Apparatus>

Next, an example of a film forming apparatus capable of performing the film forming methods according to the first and second embodiments will be described.

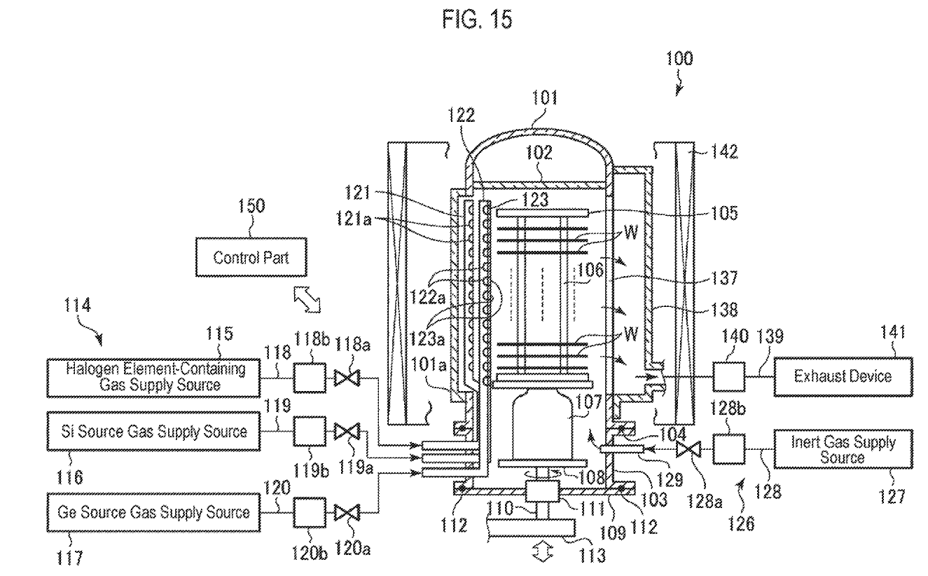

FIG. 15 is a vertical sectional view illustrating an example of a film forming apparatus capable of performing the film forming methods according to the first and second embodiments of the present disclosure. The film forming apparatus of this example is configured as a vertical batch-type apparatus.

A film forming apparatus 100 of this example has a cylindrical processing container 101 having a ceiling and an opened lower end. The entirety of the processing container 101 is formed of, for example, quartz, and a ceiling plate 102 formed of quartz is installed in the ceiling of the processing container 101 so as to seal the processing container 101. As will be described later, the processing container 101 is configured to be heated by a heating device, and is configured as a hot-wall-type film forming apparatus. A cylindrical manifold 103 formed of, for example, stainless steel is connected to the lower end opening of the processing container 101 via a seal member 104 such as an O-ring.

The manifold 103 supports the lower end of the processing container 101. From below the manifold 103, a quartz-made wafer boat 105, in which a plurality (e.g., 50 to 150 sheets) of silicon wafers (hereinafter, simply referred to as “wafers”) W as a workpiece is held in multiple stages, can be inserted into the processing container 101. The water boat 105 has, for example, three support columns 106, and the plurality of wafers W is supported by grooves formed in the support columns 106.

The wafer boat 105 is mounted on a table 108 via a heat-insulating cylinder 107 formed of quartz, and the table 108 is supported on a rotary shaft 110 that passes through a lid 109, which is formed of, for example, stainless steel and opens and closes the lower end opening of the manifold 103.

For example, a magnetic fluid seal 111 is installed in the through-portion of the rotary shaft 110 so as to rotatably support the rotary shaft 110 while hermetically sealing the rotary shaft 110. In addition, a seal member 112 such as an O-ring is interposed between the peripheral portion of the lid 109 and the lower end portion of the manifold 103 so that the sealing property inside the processing container 101 is maintained.

The rotary shaft 110 is installed at the tip end of an arm 113 supported by an elevating mechanism (not illustrated) such as a boat elevator, so that the wafer boat 105, the lid 109, and the like are moved upward and downward integrally and are inserted into the processing container 101. The table 108 may be fixedly installed in the lid 109 and the wafers W may be processed without rotating the wafer boat 105.

The film forming apparatus 100 includes a processing gas supply mechanism 114 configured to supply a processing gas into the processing container 101, an inert gas supply mechanism 126 configured to supply an inert gas, for example, N₂ gas or Ar gas, as a purge gas into the processing container 101.

The processing gas supply mechanism 114 includes a halogen element-containing gas supply source 115 configured to supply a halogen element-containing gas such as Cl₂ gas, a Si source gas supply source 116 configured to supply a Si source gas such as disilane (Si₂H₆) gas, and a Ge source gas supply source 117 configured to supply a Ge source gas such as monogermane (GeH₄) gas.

A gas supply pipe 118 configured to supply the halogen element-containing gas is connected to the halogen element-containing gas supply source 115, and a gas distribution nozzle 121 formed of a quartz tube is connected to the gas supply pipe 118. The gas distribution nozzle 121 penetrates the side wall of the manifold 103 inwardly and is bent upward to extend vertically inside the processing container 101. A plurality of gas discharge holes 121a is formed at a predetermined interval in the vertical portion of the gas distribution nozzle 121, so that the halogen element-containing gas can be substantially uniformly discharged in the processing container 101 along a horizontal direction from each of the gas discharge holes 121a. The gas supply pipe 118 is provided with an opening/closing valve 118a and a flow rate controller 118b such as a mass flow controller, so that the halogen element-containing gas can be supplied while a flow rate of the halogen element-containing gas is controlled.

A gas supply pipe 119 configured to supply the Si source gas is connected to the Si source gas supply source 116, and a gas distribution nozzle 122 formed of a quartz tube is connected to the gas supply pipe 119. The gas distribution nozzle 122 penetrates the side wall of the manifold 103 inwardly and is bent upward to extend vertically. A plurality of gas discharge holes 122a is formed at a predetermined interval along a longitudinal direction of the gas distribution nozzle 122, so that the Si source gas can be substantially uniformly discharged in the processing container 101 along the horizontal direction from each of the gas discharge holes 122a. The gas supply pipe 119 is provided with an opening/closing valve 119a and a flow rate controller 119b such as a mass flow controller, and so that the Si source gas can be supplied while a flow rate of the Si source gas is controlled.

A gas supply pipe 120 configured to supply the Ge source gas is connected to the Ge source gas supply source 117, and a gas distribution nozzle 123 formed of a quartz tube is connected to the gas supply pipe 120. The gas distribution nozzle 122 penetrates the side wall of the manifold 103 inwardly and is bent upward to extend vertically. A plurality of gas discharge holes 123a is formed at a predetermined interval along a longitudinal direction of the gas distribution nozzle 123, so that the Ge source gas can be substantially uniformly discharged in the processing container 101 along the horizontal direction from each of the gas discharge holes 123a. The gas supply pipe 120 is provided with an opening/closing valve 120a and a flow rate controller 120b such as a mass flow controller, so that the Ge source gas can be supplied while a flow rate of the Ge source gas is controlled.

The inert gas supply mechanism 126 includes an inert gas supply source 127, an inert gas pipe 128 configured to guide the inert gas from the inert gas supply source 127, and an inert gas nozzle 129 connected to the inert gas pipe 128 and penetrating the side wall of the manifold 103. The inert gas supply pipe 128 is provided with an opening/closing valve 128a and a flow rate controller 128b such as a mass flow controller, so that the inert gas can be supplied while a flow rate of the inert gas is controlled.

The processing gas supply mechanism 114 and the inert gas supply mechanism 126 constitute a gas supply mechanism.

A protruding portion 101a is formed in one side surface of the processing container 101 along a height direction, and the gas distribution nozzle 121 is arranged in the internal space of the protruding portion 101a. The gas distribution nozzles 122 and 123 are arranged such that the protruding portion 101a is interposed between the gas distribution nozzles 122 and 123. The arrangement of the gas distribution nozzles 121, 122, and 123 is not particularly limited.

When there is a gas that needs to be turned into plasma, a plasma generation mechanism may be installed in the protruding portion 101a so that the gas discharged from the gas distribution nozzle arranged in the protruding portion 101a is turned into plasma.

In a portion of the processing container 101 opposing the protruding portion 101a, an exhaust port 137 configured to evacuate the inside of the processing container 101 is formed to be elongated in the vertical direction of the side wall of the processing container 101. In a portion corresponding to the exhaust port 137 of the processing container 101, an exhaust port cover member 138 having a U shaped section is installed so as to cover the exhaust port 137. An exhaust pipe 139 configured to evacuate the inside of the processing container 101 via the exhaust port 137 is connected to the lower portion of the exhaust port cover member 138. The exhaust pipe 139 is connected to a pressure control valve 140 configured to control a pressure inside the processing container 101 and an exhaust device 141 including a vacuum pump and the like. By the exhaust device 141, the inside of the processing container 101 is evacuated via the exhaust pipe 139 and is adjusted to a predetermined depressurized state.

A cylindrical heating device 142 configured to heat the processing container 101 and the wafers W inside the processing container 101 is installed outside the processing container 101 so as to surround the processing container 101.

The film forming apparatus 100 further includes a control part 150. The control part 150 controls each component of the film forming apparatus 100, such as valves, mass flow controllers as flow rate controllers, a drive mechanism such as an elevating mechanism, and a heater power supply. The control unit 150 is composed of a CPU (computer), and includes a main control part that performs the above-described control, an input device, an output device, a display device, and a storage device. In the storage device, a storage medium that stores a program for controlling processes to be executed in the film forming apparatus 100, that is to say, processing recipes are set, and the main control part, reads a predetermined processing recipe stored in the storage medium and performs control such that a predetermined process is performed by the film forming apparatus 100 based on the processing recipe.

When the film forming apparatus 100 is dedicated to the formation of a Si film, the Ge source gas supply source 117 may be omitted. When the film forming apparatus 100 is dedicated to the formation of a Ge film, the Si source gas supply source 116 may be omitted.

Next, operations performed when forming a Si film, a Ge film, and a SiGe film using the film forming apparatus 100 configured as described above will be described. The following processing operations are executed based on the processing recipes stored in the storage medium of the storage part in the control part 150.

First, a plurality (e.g., 50 to 150 sheets) of wafers W, each of which has a clean surface to be processed by, for example, a DHF cleaning process to remove an oxide film from the surface, is loaded on the wafer boat 105, and the wafer boat 105 is inserted into the processing container 101 from below the processing container 101. Thus, the plurality of wafers W is accommodated in the processing container 101. Then, by closing the lower end opening of the manifold 103 with the lid 109, the internal space of the processing container 101 is sealed. A processing gas supply mechanism may have, for example, a COR gas supply source, and the oxide film on the surface of the wafer W may be removed by, for example, a COR process in the processing container 101.

Next, while controlling the pressure in the processing container 101 to be 1.33 to 666.6 Pa (0.01 to 5 Torr) by evacuating the inside of the processing container 101 by the exhaust device 141, an inert gas such as N₂ gas or Ar gas is supplied into the processing container 101 from the inert gas supply source 127, and under a predetermined depressurized atmosphere, the temperature of the wafers W is raised to a predetermined temperature in the range of 50 to 400 degrees C. by the heating mechanism 152.

Then, the halogen element-containing gas such as Cl₂ gas is supplied from the halogen element-containing gas supply source 115 via the gas supply pipe 118 and the gas distribution nozzle 121. By supplying the halogen element-containing gas from the gas discharge holes 121a along the surfaces of the wafers W, the halogen element is adsorbed on the surfaces to be processed of the wafers W.

Next, the inert gas is supplied to the processing container 101 and the inside of the processing container 101 is purged. Then, the temperature of the wafers W is raised to a predetermined temperature by the heating mechanism 142, and the Si source gas, the Ge source gas, or both of the Si source gas and the Ge source gas are introduced from the Si source gas supply source 116 and the Ge source gas supply source 117. Thus, a Si film, a Ge film, or a SiGe film is formed.

Since the halogen-containing element is adsorbed on the wafers W, the Si film, the Ge film, or the SiGe film is formed in a substantially complete amorphous film (an a-Si film, an a-Ge film, or an a-SiGe film).

Then, when the formed a-Si film, a-Ge film, or a-SiGe film is crystallized, in a state where the wafers W remain held inside the processing container 101, the inside of the processing container 101 is purged using the inert gas, and vacuum evacuation or an annealing process is performed in an inert gas atmosphere. By the operations as described above, the a-Si film, the a-Ge film, or the a-SiGe film is crystallized to form a single crystalline Si film, a single crystalline Ge film, or a single crystalline SiGe film.

### <Other Application>

While embodiments of the present disclosure have been described above, the present disclosure is not limited to the above-described embodiments and may be variously modified without departing from the gist of the present disclosure.

For example, in the first and second embodiments as described above, descriptions have been made with reference to the cases where an amorphous (non-crystalline) film such as an a-Si film is formed on a silicon wafer as a single crystalline substrate. However, the present disclosure is also applicable to a case where an amorphous (non-crystalline) film such as an a-Si film is formed on a single crystalline film formed on a substrate.

Although the exemplary process conditions have been described in the first and second embodiments, the processing conditions are not limited to the specific examples described above, and may be properly changed according to conditions of the film forming apparatus such as a volume of the processing container.

Further, the examples have been applied to a vertical batch-type apparatus as a film forming apparatus for carrying out the present disclosure. However, the present disclosure is not limited thereto, and a horizontal batch-type apparatus, a single wafer apparatus, and a semi-batch-type apparatus that processes multiple workpieces placed on a rotary table may also be used.

According to the present disclosure, prior to the formation of a silicon film, a germanium film, or a silicon germanium film, on a workpiece having single crystalline silicon, single crystalline germanium, or single crystalline silicon germanium as a surface to be processed, a halogen-containing substance is adsorbed on the surface to be processed. Thus, it is possible to terminate the surface of the underlying single crystal by a halogen element. Since the halogen element strongly bonds with, for example, the underlying silicon to hinder the epitaxial growth, it is possible to form a substantially complete amorphous silicon film, germanium film, or silicon germanium film on the underlying single crystal.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A method of forming a silicon film, a germanium film, or a silicon germanium film on a surface to be processed of a workpiece having single crystalline silicon, single crystalline germanium, or single crystalline silicon germanium as the surface to be processed, the method comprising:
a first process of preparing the workpiece;
a second process of adsorbing a halogen element on the surface to be processed of the workpiece; and
a third process of forming an amorphous silicon film, an amorphous germanium film, or an amorphous silicon germanium film on the surface to be processed of the workpiece by supplying a source gas for forming a silicon film, a germanium film, or a silicon germanium film to the workpiece.

2. The method of claim 1, wherein the halogen element in the second process is at least one selected from a group consisting of Cl, F, Br, and I.

3. The method of claim 1, wherein the second process includes supplying a halogen element-containing gas to the workpiece.

4. The method of claim 3, wherein the halogen element-containing gas is selected from a group consisting of Cl₂ gas, HCl gas, HBr gas, Br₂ gas, HI gas, I₂ gas, ClF₃ gas, and F₂ gas.

5. The method of claim 1, further comprising prior to the second process, a fourth process of removing an oxide film from the surface to be processed.

6. The method of claim 5, wherein the fourth process is performed using a substance containing hydrogen.

7. The method of claim 6, wherein the fourth process is performed by a chemical oxide film removal process using ammonia gas and hydrogen fluoride gas.

8. The method of claim 1, further comprising after the third process, a fifth process of crystallizing the amorphous silicon film, the amorphous germanium film, or the amorphous silicon germanium film.

9. The method of claim 8, wherein the fifth process is performed through vacuum evacuation or an annealing process.

10. The method of claim 8, wherein the fifth process is performed in-situ after the third process.

11. An apparatus of forming a silicon film, a germanium film, or a silicon germanium film on a surface to be processed of a workpiece having single crystalline silicon, single crystalline germanium, or single crystalline silicon germanium as the surface to be processed, the apparatus comprising:
a processing container configured to accommodate the workpiece in the processing container;
a gas supply mechanism configured to supply a source gas for forming the silicon film, the germanium film, or the silicon germanium film, a halogen element-containing gas, and an inert gas to the processing container;
a heating device configured to heat the workpiece;
an exhaust device configured to evacuate an interior of the processing container; and
a controller configured to control the gas supply mechanism, the heating device, and the exhaust device,
wherein the controller performs control to:
in a state in which the workpiece is disposed in the processing container, adsorb the halogen element-containing gas on the surface to be processed of the workpiece by supplying the halogen element-containing gas from the gas supply mechanism to the processing container while controlling a pressure and a temperature in the processing container by the exhaust device and the heating device; and then
form an amorphous silicon film, an amorphous germanium film, or an amorphous silicon germanium film on the surface to be processed of the workpiece by supplying the source gas from the gas supply mechanism to the surface to be processed of the workpiece.

12. The apparatus of claim 11, wherein the controller further performs control to, after the amorphous silicon film, the amorphous germanium film, or the amorphous silicon germanium film is formed on the surface to be processed of the workpiece, crystallize the amorphous silicon film, the amorphous germanium film, or the amorphous silicon germanium film by vacuum evacuating the interior of the processing container by the exhaust device or by annealing the workpiece in the processing container by the heating device.
